(19) United States
(12) Patent Application Publication
(10) Pub. No.: US 2024/0047228 A1
(43) Pub. Date: Feb. 8, 2024

(54) METHODS FOR CONSTRUCTING PACKAGE SUBSTRATES WITH HIGH DENSITY

(71) Applicant: Advanced Micro Devices, Inc., Santa Clara, CA (US)

(72) Inventors: Sri Ranga Sai Boyapati, Austin, TX (US); Deepak Vasant Kulkarni, Austin, TX (US); Raja Swaminathan, Austin, TX (US); Brett P. Wilkerson, Austin, TX (US); Arsalan Alam, Austin, TX (US)

(73) Assignee: Advanced Micro Devices, Inc., Santa Clara, CA (US)

(21) Appl. No.: 17/816,944

(22) Filed: Aug. 2, 2022

(51) Int. Cl. H01L 21/48; H01L 23/64; H01L 23/498

(52) U.S. Cl. CPC H01L 21/486; H01L 21/4857; H01L 23/642; H01L 23/49822; H01L 23/49838; H01L 23/49894

(57) ABSTRACT

A disclosed method can include (i) positioning a first surface of a component of a semiconductor device on a first plated through-hole, (ii) covering, with a layer of dielectric material, at least a second surface of the component that is opposite the first surface of the component, (iii) removing a portion of the layer of dielectric material covering the second surface of the component to form at least one cavity, and (iv) depositing conductive material in the cavity to form a second plated through-hole on the second surface of the component. Various other apparatuses, systems, and methods are also disclosed.

### BACKGROUND

To achieve increasing power delivery demands of semiconductor device products, discrete components such as voltage regulators and capacitors can be embedded in a package substrate. As described in greater detail below, this application discloses both problems and corresponding solutions related to the embedding of discrete components.

### BRIEF DESCRIPTION OF THE DRAWINGS

The accompanying drawings illustrate a number of exemplary implementations and are a part of the specification. Together with the following description, these drawings demonstrate and explain various principles of the instant disclosure.

FIG. 1 shows a first portion of an illustrative workflow for embedding a component within a substrate.

FIG. 2 shows a second portion of the illustrative workflow for embedding a component within a substrate.

FIG. 3 shows a flow diagram for an illustrative method for embedding a component within a substrate.

FIG. 4 shows a first portion of another illustrative workflow for embedding a component within a substrate.

FIG. 5 shows a second portion of another illustrative workflow for embedding a component within a substrate.

FIG. 6 shows a third portion of another illustrative workflow for embedding a component within a substrate.

FIG. 7 shows a fourth portion of another illustrative workflow for embedding a component within a substrate.

FIG. 8 shows a comparison between a result of one illustrative method for embedding a component within a substrate and a result of a different and improved method for embedding a component within a substrate.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

The present disclosure describes various methods for embedding components within substrates with high density. To meet increasing power delivery demands of semiconductor products, discrete components such as voltage regulators and capacitors can be embedded within a package substrate at a position closer to the die. This application describes the creation of a package substrate construction that can embed one or more components in a high density configuration of plated through-holes.

The technology of this application can solve a number of different problems. Related power delivery solutions in the field of package substrates can have no flexibility or scalability. In addition, an approach using an air core inductor can be dependent on package thickness. For thin packages, the inductance values can generally be too low to be implemented. Another approach of including magnetic materials in plated through-holes can cause the plated through-hole pitch to be very coarse, which can render scaling of plated through-hole density infeasible. This last approach can also involve very high manufacturing complexity due to leaching of magnetic fillers to various wet chemistries in the process flow. In contrast, the technology of this application can be highly scalable, with an effective doubling of plated through-hole density in comparison to a related or conventional package structure. The technology of this application can also be highly flexible in terms of embedding components of various dimensions within a package core. In summary, related technologies involving an air core inductor, a magnetic core inductor, and/or a multilayer ceramic capacitor have significant limitations in terms of flexibility and scalability.

In view of the above, the technology of this application can introduce a variety of improvements over related methodologies. For example, the technology of this application can achieve a high plated two-hole density due to a lower plated through-hole pitch. In addition, the technology of this application can enable the embedding of components of varying thicknesses. The technology of this application can also enable the embedding of components without the usage of a cavity drill and without the associated spacing overhead (e.g., spacing along X and Y coordinates for a plan view of a corresponding semiconductor device).

Additionally, the technology of this application can enable components of different dimensions (e.g., varying along each of X, Y, and/or Z dimensions) to be embedded without creating process complexities and/or yield challenges. In related embedding approaches, the component thickness has to be close to the substrate core thickness. Due to this constraint, embedding components within a thick core of over 800 microns thickness can become impractical. Accordingly, example approaches disclosed in this application can enable significant increases in plated through-hole density. Additionally, the technology of this application can also facilitate the efficient design of semiconductor device packages.

The technology of this application can include a number of distinguishing features. In some examples, high plated through-hole density with 250-300 microns pitch can constitute one distinguishing feature. In further examples, components embedded at various layers of the core would be another distinguishing feature, because related methodologies can only embed such components within a single layer (e.g., a single composite layer formed by joining a top layer and a bottom layer, whereas the technology of this application can result in an arbitrary number of layers until reaching a target thickness). Similarly, in further examples, another distinguishing feature of this application can be that different component types with different thicknesses can be embedded in the core.

As will be described in greater detail below, the instant disclosure generally relates to methods for constructing package substrates with high density. An illustrative method can include (i) positioning a first surface of a component of a semiconductor device on a first plated through-hole, (ii) covering, with a layer of dielectric material, at least a second surface of the component that is opposite the first surface of the component, (iii) removing a portion of the layer of dielectric material covering the second surface of the component to form at least one cavity, and (iv) depositing conductive material in the cavity to form a second plated through-hole on the second surface of the component.

In some examples, the first plated through-hole is positioned such that a pitch of a plated through-hole pattern is less than approximately 500 microns.

In some examples, the first plated through-hole is positioned such that a pitch of a plated through-hole pattern is less than approximately 350 microns.

In some examples, the first plated through-hole is positioned such that a pitch of a plated through-hole pattern is approximately 250 microns.

In some examples, a thickness of the layer of dielectric material is approximately 50-100 microns.

In some examples, the first surface of the component of the semiconductor device is positioned prior to covering the second surface of the component with the layer of dielectric material such that a cavity drill is not used to form a space in which the component is disposed.

In some examples, the method further includes adding contacts formed of the conductive material to the second surface of the component of the semiconductor device prior to covering the second surface of the component with the layer of dielectric material.

In some examples, the method further includes repeating at least a portion of the method to form a second layer of dielectric material.

In some examples, the portion of the method is repeated until a predefined thickness of a substrate core for the semiconductor device is achieved.

In some examples, the component of the semiconductor device includes at least one of a capacitor or a voltage regulator.

An example semiconductor substrate can include a component embedded within a dielectric layer, a first plated through-hole electrically connected to a first surface of the component, and a second plated through-hole electrically connected to a second surface of the component opposite the first surface. In these examples, a pitch of a plated through-hole pattern within the semiconductor substrate is less than approximately 550 microns.

Similarly, an example semiconductor device can include a component embedded within a dielectric layer, a first plated through-hole electrically connected to a first surface of the component, and a second plated through-hole electrically connected to a second surface of the component opposite the first surface. In these examples, a pitch of a plated through-hole pattern within a corresponding semiconductor substrate is less than approximately 550 microns.

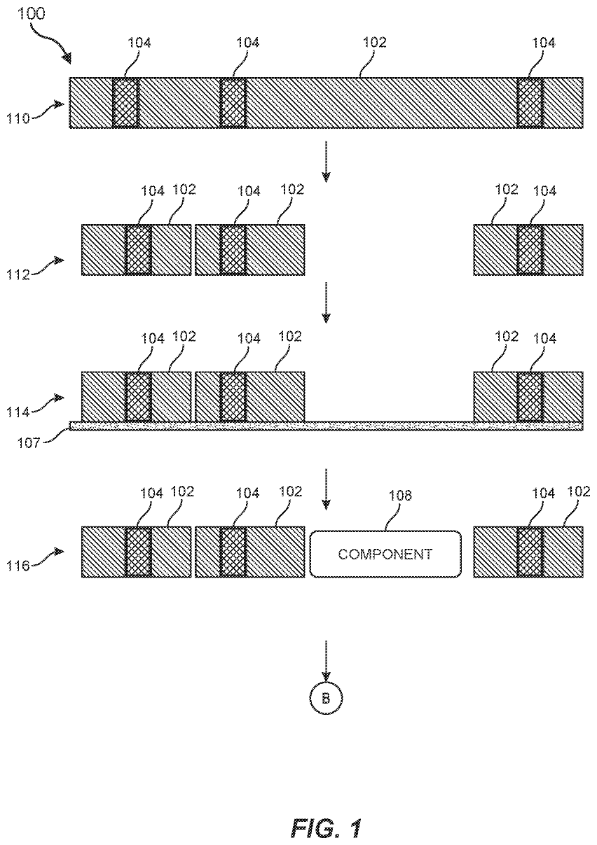

FIG. 1 shows an illustrative workflow 100, which can include a workflow step 110, a workflow step 112, a workflow step 114, and a workflow step 116. Workflow 100 can correspond to a methodology of the related art upon which the technology of this application can improve. Workflow 100 can begin at workflow step 110, at which point a substrate core formed of an appropriate dielectric can be obtained or created. As one illustrative example, pre-preg can form substrate 102 shown at workflow step 110, but in other examples a different and suitable dielectric material can be used.

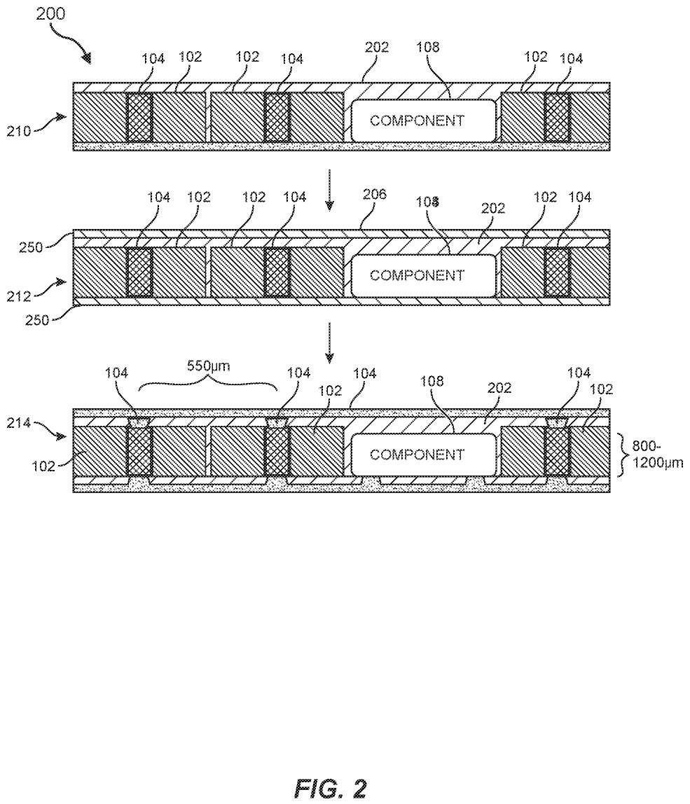

As further shown in this figure, the substrate core can have a plurality of plated through-holes 104. Moreover, the plated through-holes 104 can have a particular pitch, which can refer to a distance between the center of two plated through-holes, within a pattern of plated through-holes, when not otherwise obstructed by a component. In the example of workflow step 110, the two plated through-holes 104 on the left can have a particular pitch of about 550 microns (see workflow step 214 of FIG. 2), whereas the plated through-hole on the right side at workflow step 110 does not necessarily define or correspond to this specific pitch, due to the obstruction of a component 108, as discussed further below.

At workflow step 112, a cavity drill can be used to form a cavity within substrate 102. The cavity drill can be used to form the cavity in order to later dispose a component within the cavity. The component can correspond to a capacitor or a voltage regulator, for example. In one specific example, the capacitor can correspond to a silicon capacitor. In other examples, any other suitable or appropriate discrete component or integrated passive device can be used and embedded within the cavity that was formed at workflow step 112 using the cavity drill.

At workflow step 114, a tape lamination procedure can be performed to laminate a tape layer 107 at the bottom of a remainder of substrate 102 after the creation of the cavity. Subsequently, at workflow step 116, a component 108 such as a silicon capacitor can be placed appropriately within the previously formed cavity. According to the methodology of workflow 100, component 108 can be constrained in terms of its thickness such that the thickness is substantially the same as the thickness of substrate 102.

From FIG. 1, workflow 100 can proceed in the form of workflow 200 shown in FIG. 2. Workflow 200 can include a workflow step 210, a workflow step 212, and a workflow step 214. At workflow step 210, component 108 can be encapsulated within another dielectric material. As one illustrative example, the second and distinct dialectic material can correspond to Ajinomoto Build-up Film. Thus, although it can be desirable to use the same or similar dielectric material as in workflow 100, and as described above, such as pre-preg, pre-preg might not have sufficient fluidity or other material properties to appropriately flow into the cavity formed by the cavity drill at workflow step 112. Accordingly, at workflow step 210, the second and distinct dielectric material (e.g., Ajinomoto Build-up Film) can be used. Similarly, at workflow step 212, a second layer 250 of the second and distinct dielectric material can be formed on both the top and the bottom surface of substrate 102 (e.g., a second layer of Ajinomoto Build-up Film on top of the previous Ajinomoto Build-up Film).

Lastly, at workflow step 214, vias corresponding to the plated through-holes can be formed using a suitable procedure, such as a lasering procedure. The lasering procedure can electrically connect plated through-holes 104 to an exterior and/or to component 108 such as a silicon capacitor. Additionally, a metallization procedure can be performed to ensure that a metal or other conductive material forming the plated through-holes achieves electrical connectedness.

Moreover, as further shown in FIG. 2, workflow step 214 further highlights how the plated through-holes of this methodology together have a relatively large pitch corresponding to approximately 550 microns. Similarly, workflow step 214 also further highlights how the height or thickness of the original substrate 102, which is constrained to substantially match the height or thickness of component 108 according to this methodology, is relatively large and inflexible at approximately 800-1200 microns.

As further discussed above, the methodology of FIGS. 1-2 can have a number of deficiencies, undesirable properties, or suboptimizations. The pitch of approximately 550 microns is relatively large, which also results in less component density or functionality per millimeter squared of real estate on the corresponding substrate. The relatively large pitch also results in the plated through-holes being so large that they must include voids within their center. Additionally, a size of the component (e.g., along each of three dimensions X, Y, and/or Z) is relatively inflexible, and is furthermore constrained to substantially match the height or thickness 800-1200 microns of the original substrate. As another example, the methodology of FIGS. 1-2 involves the use of the cavity drill. Moreover, this methodology can also be essentially constrained to the single layer (e.g., a composite layer formed by merging a top sub-layer and a bottom sub-layer), as further shown in FIGS. 1-2.

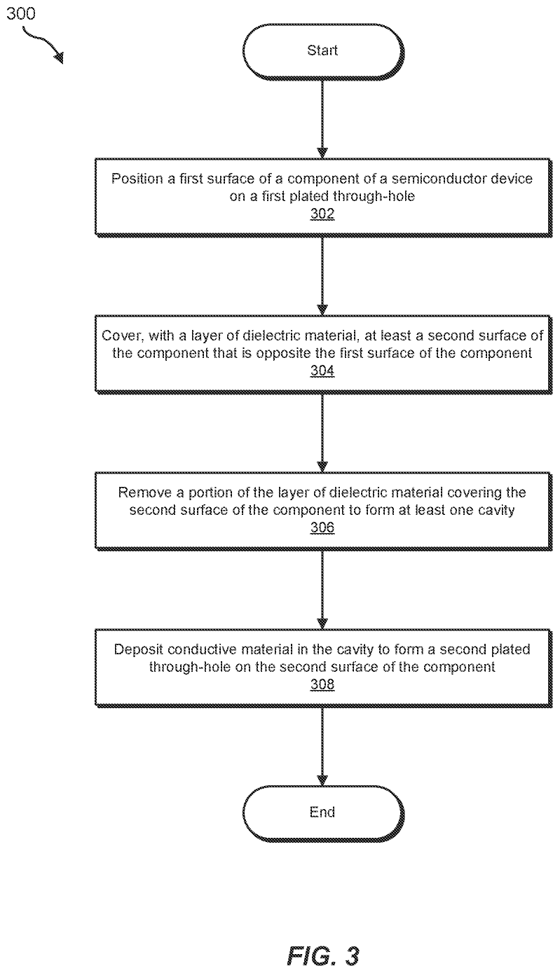

In view of the above, FIG. 3 shows an illustrative flow diagram of a method 300 for embedding a component within a substrate. Method 300 can address one or more of the deficiencies outlined above, and can improve upon the methodology of FIGS. 1-2, for example. At step 302, one or more of the systems described herein (e.g., a semiconductor manufacturing facility) can position a first surface of a component of a semiconductor device on a first plated through-hole.

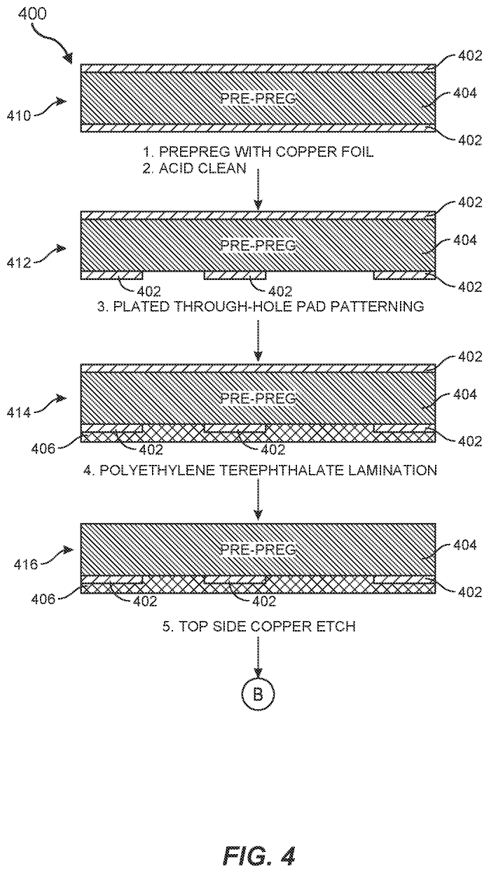

Step 302 can be performed in a variety of ways. By way of illustrative example, FIGS. 4-7 show a sequence of workflows that highlight a more detailed implementation of method 300. In particular, the methodology of FIGS. 4-7 can include multiple preparation steps prior to the performance of step 302. These preparation steps can prepare the corresponding substrate and/or prepare a layer of one or more plated through-holes upon which a component, such as a silicon capacitor, can be placed in accordance with step 302.

FIG. 4 shows an illustrative workflow 400, which can further include a workflow step 410, a workflow step 412, a workflow step 414, and a workflow step 416. At workflow step 410, an original semiconductor substrate can be created or obtained. The semiconductor substrate can include a layer of dielectric material 404 with a thinner conductive metal layer 402 on both the top side of dielectric material 404 and the bottom side of dielectric material 404. One illustrative example of the dielectric material can include pre-preg. Similarly, an illustrative example of the conductive material for metal layer 402 can include copper. In other examples, however, any different and suitable dielectric material and/or metal or other conductive material can be used for dielectric material 404 and metal layer 402. In particular, at workflow step 410, a copper foil can be placed on the top surface and the bottom surface of a base portion of pre-preg, as further shown in FIG. 4. Additionally, at workflow step 410, an acid cleaning procedure can be performed to eliminate particles or obstructions, or to otherwise ensure clean surfaces for the remainder of the workflows of FIGS. 4-7.

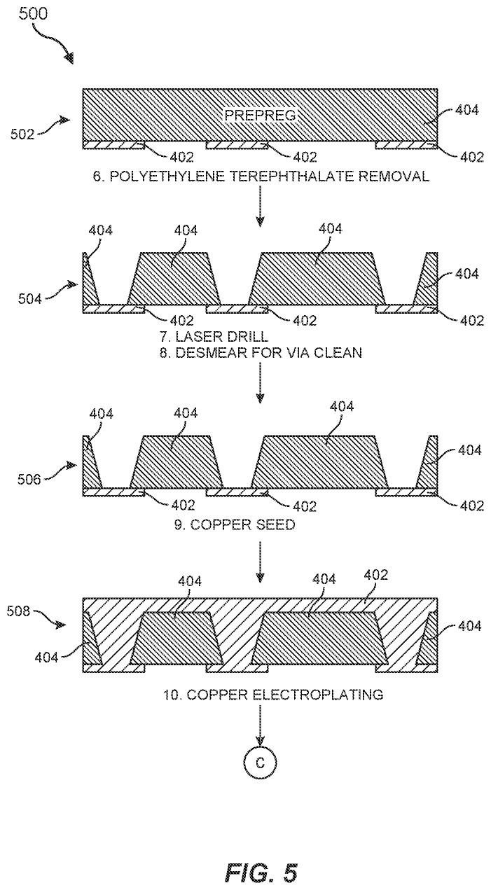

From workflow step 410, workflow 400 can proceed to a workflow step 412, at which point a plated through-hole pad patterning procedure can be performed, by eliminating selected portions from metal layer 402 at the bottom of dielectric material 404. After eliminating, removing, or carving out the selected portions from metal layer 402, the remaining portions (as shown at workflow step 412 in FIG. 4) can form the top surfaces of corresponding plated through-holes, as further discussed below in connection with FIGS. 5-7.

From workflow step 412, workflow 400 can proceed to a workflow step 414, at which point a polyethylene terephthalate lamination procedure can be performed. The performance of the polyethylene terephthalate lamination procedure can effectively laminate the bottom surface of dielectric material 404, including the remaining portions of metal layer 402 at the bottom, with a layer of polyethylene terephthalate 406.

From workflow step 414, workflow 400 can proceed to a workflow step 416, at which point a top-side etching procedure can be performed. The etching procedure of workflow step 414 can be performed to substantially or entirely remove metal layer 402 on the top surface of dielectric material 404. Accordingly, at workflow step 416, FIG. 4 shows how this particular instance of metal layer 402 has been removed.

From FIG. 4, workflow 400 proceeds in the form of a workflow 500 shown in FIG. 5. Workflow 500 can further include a workflow step 502, a workflow step 504, a workflow step 506, and a workflow step 508. At workflow step 502, polyethylene terephthalate 406 that was previously placed at workflow step 414 can be removed. Accordingly, at workflow step 502, FIG. 5 further shows how layer of polyethylene terephthalate 406 has been removed.

From workflow step 502, workflow 500 can proceed to a workflow step 504, at which point one or more cavities can be created within dielectric material 404. Accordingly, at workflow step 504, FIG. 5 further illustrates how multiple cavities, in substantially trapezium shapes, have been effectively created or carved into dielectric material 404. In some illustrative examples, the creation of these trapezium shaped cavities can be performed at least in part using a laser drill. Thus, usage of the laser drill can contrast with usage of the cavity drill described above in connection with FIGS. 1-2 because the methodology of FIGS. 4-7 can omit any usage of a cavity drill. Additionally, at workflow step 504, and after the performance of laser drilling to create the corresponding cavities, a desmearing operation can be performed to effectively clean the corresponding vias or plated through-holes.

From workflow step 504, workflow 500 can proceed to a workflow step 506, at which point a copper seeding procedure can be performed. Although not necessarily shown in FIG. 5 due to scale, a thin layer of copper can be disposed on top of a remainder of dielectric material 404 after the creation of the cavities using the laser drill at workflow step 504. In some examples, the copper seeding procedure can correspond to an electroless copper seeding procedure.

From workflow step 506, workflow 500 can proceed to a workflow step 508, at which point a copper electroplating procedure can be performed to deposit or fill copper within the cavities created at workflow step 504. In addition to filling these cavities, a horizontal layer of copper can be formed above the cavities and branching between them, as further shown in FIG. 5 at workflow step 508.

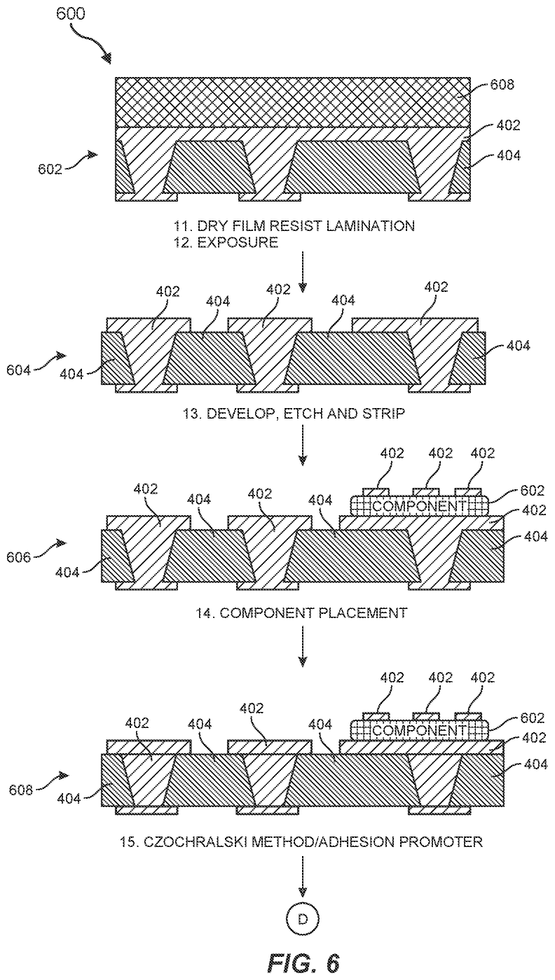

From FIG. 5, workflow 500 can proceed in the form of a workflow 600 shown in FIG. 6. Workflow 600 can include a workflow step 602, a workflow step 604, a workflow step 606, and a workflow step 610. At workflow step 602, a dry film resist lamination procedure can be performed to laminate a dry film resist layer 608 onto a topside surface of copper 402 that was disposed through copper electroplating at workflow step 508, as further discussed above. Additionally, after laminating dry film resist layer 608 to the topside surface of copper 402, an exposure procedure can be performed in which dry film resist layer 608 can be exposed, such as by removing a protective film.

From workflow step 602, workflow 600 can proceed to a workflow step 604, at which point a combination of copper 402 and dielectric material 404 can be appropriately developed, edged, and stripped. These procedures at workflow step 604 can effectively remove dry film resist layer 608, which was laminated onto a top surface of dielectric material 402 at workflow step 602.

From workflow step 604, workflow 600 can proceed to a workflow step 606, which can also correspond to step 302 of method 300, as further discussed above. At workflow step 606, a component 602 can be disposed on a top surface of copper 402 forming a plated through-hole. Placing the component on the top surface can electrically connect the component through the plated through-hole to an exterior and/or to one or more layers of a corresponding stack beneath component 602. Moreover, at workflow step 606, further instances of copper 402 in the form of conductive contacts can be disposed on a top surface of component 602. FIG. 6 shows an illustrative example of three separate instances of copper 402 being disposed on a top surface of component 602, but in other examples any other arbitrary or suitable number of conductive contacts can be placed on the top surface.

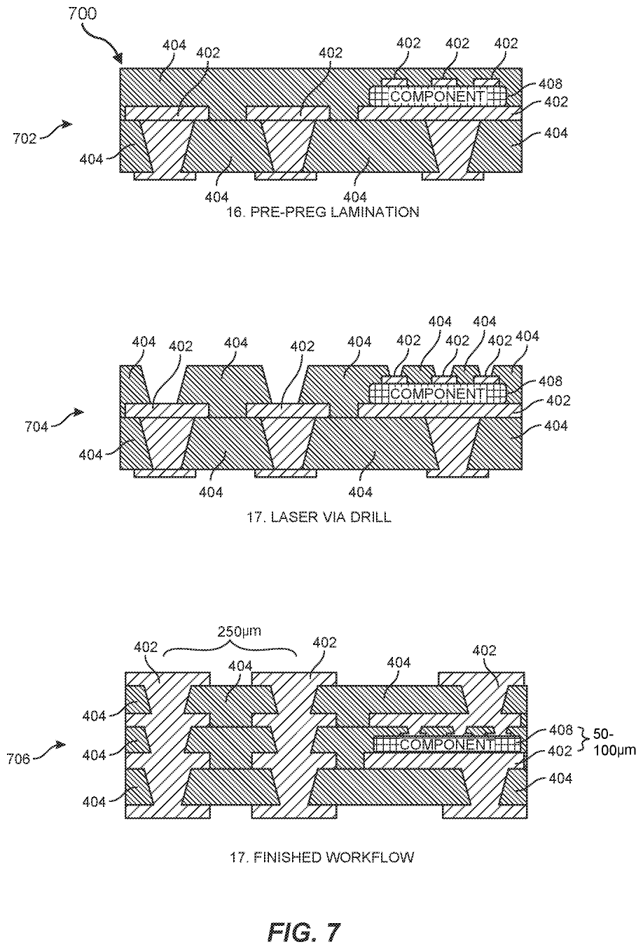

Additionally, workflow 600 can also include a workflow step 608, at which point a small adhesion promoter can be applied to the surface of copper 402 at the tops and bottoms of the plated through-holes, as well as on the contacts on top of the component. The adhesion promoter can be applied according to the Czochralski method, for example. The adhesion promoter can promote adhesion of a second layer of dielectric material that can be disposed on top of the plated through-holes, as further discussed below in the context of workflow step 702 of FIG. 7.

Returning to FIG. 3, at step 304 of method 300, one or more of the systems described herein can cover, with a layer of dielectric material, at least a second surface of the component that is opposite the first surface of the component. Similarly, from workflow step 606, workflow 600 can proceed in the form of a workflow 700 shown in FIG. 7. Workflow 700 can further include a workflow step 702, a workflow step 704, and a workflow step 706, as further shown in this figure. In particular, workflow step 702 can correspond to step 304 of method 300, at which point a second layer of dielectric material 404 can be disposed over component 408 as well as copper 402 forming the conductive contacts on the top surface of component 408. Thus, between the original layer of dielectric material 404 and the second layer of dielectric material 404 laminated at workflow step 702, the overall layers filling the voids between the plated through-holes in the component can be substantially uniform (e.g., can be substantially the same dielectric material, such as pre-preg), whereas the methodology of FIGS. 1-2 resulted in mixed and non-uniform layers of dielectric (e.g., featuring both Ajinomoto Build-up Film and pre-preg).

Returning to FIG. 3, at step 306 of method 300, one or more of the systems herein can remove a portion of the layer of dielectric material covering the second surface of the component to form at least one cavity. Similarly, at workflow step 704, workflow 700 can proceed with a drilling procedure to create one or more vias or plated through-holes, as further shown in FIG. 7. Thus, the use of the drilling procedure, such as a laser drilling procedure, can create substantially trapezium shaped cavities that essentially parallel the trapezium shaped plated through-holes beneath them (which were previously filled with copper 402 at the copper electroplating procedure of workflow step 508).

Returning again to FIG. 3, at step 308, one or more of the systems described herein can deposit conductive material in the cavity to form a second plated through-hole on the second surface of the component. Similarly, at workflow step 706, one or more of the previous steps for method 300 and workflows 400-700 can be repeated, as desired, until a predefined or target thickness of the corresponding substrate core is achieved. Thus, in the example of workflow step 706, essentially three layers of substantially uniform dielectric material (e.g., pre-preg) can be stacked on top of each other, thereby encapsulating the component, the component contacts, and the plated through-holes, as further discussed above. Moreover, at workflow step 706, FIG. 7 further illustrates how a corresponding pitch of a plated through-hole pattern formed by corresponding ones of plated through-holes 402 can be substantially approximately 250 microns. Similarly, a height or thickness of the dielectric layer encapsulating the component is substantially or approximately 50-100 microns.

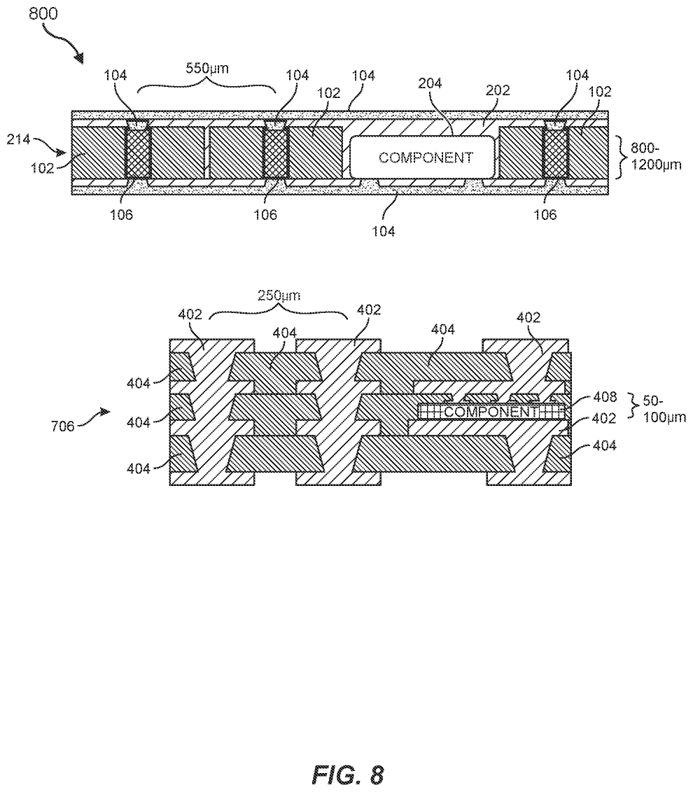

In summary, FIG. 8 shows a comparison diagram 800, which compares a repetition of the final result of the methodology of FIGS. 1-2 (see workflow step 214) at the top with a final result of the methodology of FIGS. 3-7 (see workflow step 706) at the bottom. As further shown in FIG. 8, the solution illustrated at the bottom achieves a substantially tighter and more desirable pitch of a pattern of plated through-holes, at approximately 250-300 microns, in comparison to the substantially larger and less desirable pitch of approximately 550 microns according to the methodology illustrated at the top. Similarly, whereas the component of workflow step 214 is substantially constrained in terms of height or thickness to match the approximately 800-1200 microns height or thickness of the corresponding dielectric material forming the substrate, the component of workflow step 706 can be flexible in terms of its size along one or more of three separate dimensions. Similarly, the height of the dialectic layer encapsulating the component at workflow step 706 can be substantially smaller at approximately 50-100 microns. Moreover, the solution of workflow step 706 can be effectively repeated, as further discussed above, thereby creating two, three, or more layers as part of a stack to form the substrate. Furthermore, although the bottom of FIG. 8 shows only a single component embedded within the middle layer, the solution of workflow step 706 and/or method 300 can be substantially or partially repeated to embed multiple different components, of various shapes, sizes, and types, in one or more (or every one) of the multiples layers stacked on top of each other. In contrast, the solution of workflow step 214 is substantially constrained to a single layer (which can be formed as a composite of a top sub-layer and a bottom sub-layer, but which cannot necessarily achieve a 3+ layer configuration shown at workflow step 706, for example). Additionally, as further discussed above, the solution corresponding to workflow step 706 can effectively eliminate the usage of the cavity drill and the usage of mixed dielectrics (e.g., both pre-preg and Ajinomoto Build-up Film), resulting in the more uniform and easier to manage dielectric layers (e.g., uniform prep-preg) shown at workflow step 706. Thus, as shown in FIG. 8 at the bottom, the component 408, a top surface of the first plated through-hole beneath component 408, and a bottom surface of the second plated through-hole on top of component 408 are embedded within a dielectric layer formed of a substantially uniform dielectric material. Lastly, the solution corresponding to workflow step 706 can eliminate the voids within the plated through-holes, which were previously discussed in the context of FIGS. 1-2.

For completeness, the above discussion relates to semiconductor devices including computer processors. Such processors can include and/or represent any type or form of hardware-implemented device capable of interpreting and/or executing computer-readable instructions. In one example, the processor can include and/or represent one or more semiconductor devices implemented and/or deployed as part of a computing system. One example of the processor includes central processing units (CPUs) and microprocessors. Other examples, depending on context, can include microcontrollers, field-programmable gate arrays (FPGAs) that implement softcore processors, application-specific integrated circuits (ASICs), systems on a chip (SoCs), portions of one or more of the same, variations or combinations of one or more of the same, and/or any other suitable processor.

The processor can implement and/or be configured with any of a variety of different architectures and/or microarchitectures. For example, the processor can implement and/or be configured as a reduced instruction set computer (RISC) architecture or the processor can implement and/or be configured as a complex instruction set computer (CISC) architecture. Additional examples of such architectures and/or microarchitectures include, without limitation, 16-bit computer architectures, 32-bit computer architectures, 64-bit computer architectures, x86 computer architectures, advanced RISC machine (ARM) architectures, microprocessor without interlocked pipelined stages (MIPS) architectures, scalable processor architectures (SPARCs), load-store architectures, portions of one or more of the same, combinations or variations of one or more of the same, and/or any other suitable architectures or microarchitectures.

In some examples, the processor can include and/or incorporate one or more further components that are not explicitly represented and/or illustrated in the figures. Examples of such components include, without limitation, registers, memory devices, circuitry, transistors, resistors, capacitors, diodes, connections, traces, buses, semiconductor (e.g., silicon) devices and/or structures, combinations or variations of one or more of the same, and/or any other suitable components.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered exemplary in nature since many other architectures can be implemented to achieve the same functionality.

The apparatuses, systems, and methods described herein can employ any number of software, firmware, and/or hardware configurations. For example, one or more of the exemplary implementations and/or implementations disclosed herein can be encoded as a computer program (also referred to as computer software, software applications, computer-readable instructions, and/or computer control logic) on a computer-readable medium. The term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives and floppy disks), optical-storage media (e.g., Compact Disks (CDs) and Digital Video Disks (DVDs)), electronic-storage media (e.g., solid-state drives and flash media), and/or other distribution systems.

In addition, one or more of the modules, instructions, and/or micro-operations described herein can transform data, physical devices, and/or representations of physical devices from one form to another. Additionally or alternatively, one or more of the modules, instructions, and/or micro-operations described herein can transform a processor, volatile memory, non-volatile memory, and/or any other portion of a physical computing device from one form to another by executing on the computing device, storing data on the computing device, and/or otherwise interacting with the computing device.

The process parameters and sequence of the steps described and/or illustrated herein are given by way of example only and can be varied as desired. For example, while the steps illustrated and/or described herein can be shown or discussed in a particular order, these steps do not necessarily need to be performed in the order illustrated or discussed. The various exemplary methods described and/or illustrated herein can also omit one or more of the steps described or illustrated herein or include further steps in addition to those disclosed.

Various implementations are described herein with sufficient detail to enable one skilled in the art to practice the disclosure. It is understood that the various implementations of the disclosure, although different, are not necessarily exclusive and can be combined differently because they show novel features. For example, a particular feature, structure, step of manufacturing, or characteristic described in connection with one implementation can be implemented within other implementations without departing from the spirit and scope of the disclosure. In addition, it is understood that the location and arrangement of individual elements, such as geometrical parameters within each disclosed implementation, can be modified without departing from the spirit and scope of the disclosure. Other variations will also be recognized by one of ordinary skill in the art. The following detailed description is, therefore, not to be taken in a necessarily limiting sense.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the instant disclosure. The implementations disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A method comprising:
positioning a first surface of a component of a semiconductor device on a first plated through-hole;
covering, with a layer of dielectric material, at least a second surface of the component that is opposite the first surface of the component;
removing a portion of the layer of dielectric material covering the second surface of the component to form at least one cavity; and
depositing conductive material in the cavity to form a second plated through-hole on the second surface of the component.

2. The method of claim 1, wherein the first plated through-hole is positioned such that a pitch of a plated through-hole pattern is less than approximately 500 microns.

3. The method of claim 1, wherein the first plated through-hole is positioned such that a pitch of a plated through-hole pattern is less than approximately 350 microns.

4. The method of claim 1, wherein the first plated through-hole is positioned such that a pitch of a plated through-hole pattern is approximately 250 microns.

5. The method of claim 1, wherein a thickness of the layer of dielectric material is approximately 50-100 microns.

6. The method of claim 1, wherein the first surface of the component of the semiconductor device is positioned prior to covering the second surface of the component with the layer of dielectric material such that a cavity drill is not used to form a space in which the component is disposed.

7. The method of claim 1, further comprising adding contacts formed of the conductive material to the second surface of the component of the semiconductor device prior to covering the second surface of the component with the layer of dielectric material.

8. The method of claim 1, further comprising repeating at least a portion of the method to form a second layer of dielectric material.

9. The method of claim 8, wherein the portion of the method is repeated until a predefined thickness of a substrate core for the semiconductor device is achieved.

10. The method of claim 1, wherein the component of the semiconductor device comprises at least one of a capacitor or a voltage regulator.

11. A semiconductor substrate comprising:
a component;
a first plated through-hole electrically connected to a first surface of the component; and
a second plated through-hole electrically connected to a second surface of the component opposite the first surface;
wherein the component, a top surface of the first plated through-hole, and a bottom surface of the second plated through-hole are embedded within a dielectric layer formed of a substantially uniform dielectric material.

12. The semiconductor substrate of claim 11, wherein the dielectric material is pre-preg.

13. The semiconductor substrate of claim 11, wherein the first plated through-hole is positioned such that a pitch of a plated through-hole pattern is less than approximately 350 microns.

14. The semiconductor substrate of claim 11, wherein the first plated through-hole is positioned such that a pitch of a plated through-hole pattern is approximately 250 microns.

15. The semiconductor substrate of claim 11, wherein a thickness of the dielectric layer is approximately 50-100 microns.

16. The semiconductor substrate of claim 11, wherein the first surface of the component of the semiconductor substrate is positioned prior to covering the second surface of the component with the dielectric layer such that a cavity drill is not used to form a space in which the component is disposed.

17. The semiconductor substrate of claim 11, further comprising contacts formed of a conductive material at the second surface of the component of the semiconductor substrate.

18. The semiconductor substrate of claim 11, wherein the semiconductor substrate is formed of at least three layers of the dielectric material.

19. The semiconductor substrate of claim 18, wherein the at least three layers of the dielectric material are formed of pre-preg.

20. A method comprising:
positioning a first surface of a first component of a semiconductor device on a first plated through-hole;
covering, with a first layer of dielectric material, at least a second surface of the first component that is opposite the first surface of the first component;
removing a portion of the first layer of dielectric material covering the second surface of the first component to form at least one first cavity;
depositing conductive material in the first cavity to form a second plated through-hole on the second surface of the first component; and
repeating a portion of the method for a second component to form a second cavity in a second layer of dielectric material and embed the second component within the second layer of dielectric material over the first layer of dielectric material.
